(19) United States
(12) Patent Application Publication
(10) Pub. No.: US 2021/0029830 A1
(43) Pub. Date: Jan. 28, 2021

(54) METHOD FOR PRODUCING A FLEXIBLE DEVICE, FLEXIBLE ELECTRONIC DEVICE AND FLEXIBLE ARRANGEMENT OF A PLURALITY OF ELECTRONIC DEVICES

(71) Applicant: Applied Materials, Inc., Santa Clara, CA (US)

(72) Inventors: John MALTABES, Alzenau (DE); Jens DEGENHARDT, Jüchen (DE)

(73) Assignee: Applied Materials, Inc., Santa Clara, CA (US)

(21) Appl. No.: 17/040,837

(22) PCT Filed: Mar. 26, 2018
(86) PCT No.: PCT/EP2018/057645

§ 371 Date: Sep. 23, 2020

(51) Int. Cl. H05K 3/00; H05K 1/18

(52) U.S. Cl. CPC H05K 3/007; H05K 2203/0147; H05K 1/189

(57) ABSTRACT

A method for producing a flexible device is described. The method includes providing a support substrate, coating the support substrate with an adhesive layer, providing a device having a microstructure on the adhesive layer, attaching a flexible substrate to the device, and removing the adhesive layer.

### TECHNICAL FIELD

Embodiments of the disclosure relate to methods of producing flexible devices. In particular, embodiments of the disclosure relate to methods of producing a flexible electronic device, particularly an optoelectronic device. Further, embodiments of the disclosure relate to methods of producing an arrangement of a plurality of flexible devices, particularly a plurality of electronic devices.

### BACKGROUND

Processing of flexible substrates, such as plastic films or foils, is in high demand in the packaging industry, semiconductor industries and other industries. Processing may consist of coating a flexible substrate with a material, such as a metal, in particular aluminum, semiconductors and dielectric materials, being etched and other processing actions being conducted on a substrate for the respective applications. Systems performing this task generally include a process drum, e.g., a cylindrical roller, coupled to a processing system for transporting the substrate, and on which at least a portion of the substrate is processed. Accordingly, Roll-to-roll (R2R) coating systems can provide a high throughput system.

Further, there is a continuous demand for Roll-to-Roll deposition systems and a strong increase in demand is particularly being experienced in microelectronic industry and photovoltaic (PV) industry. For example, the use of touch panel elements, flexible displays and flexible PV modules results in an increasing demand for depositing suitable layers or providing microelectronic structures on flexible substrates, particularly suitable for in Roll-to-Roll production which is of particular interest because of low manufacturing costs.

Accordingly, there is a continuous demand for improved methods for producing flexible devices.

### SUMMARY

In light of the above, a method for producing a flexible device and a flexible electronic device as well as a flexible arrangement of a plurality of electronic devices according to the independent claims are provided. Further aspects, advantages, and features are apparent from the dependent claims, the description, and the accompanying drawings.

According to an aspect of the present disclosure, a method for producing a flexible device is provided. The method includes providing a support substrate, coating the support substrate with an adhesive layer, providing a device having a microstructure on the adhesive layer, attaching a flexible substrate to the device, and removing the adhesive layer.

According to a further aspect of the present disclosure, a method for producing a flexible device is described. The method includes providing a support substrate and coating the support substrate with a temporary adhesive layer. The temporary adhesive layer consists of a decomposable material. The decomposable material is decomposable by exposing the decomposable material to a solvent, particularly an aqueous solvent. Additionally or alternatively, the decomposable material is decomposable by exposing the decomposable material to light, particularly to UV-light. Further, the method includes providing a device having a microstructure on the temporary adhesive layer by employing an imprint process and/or a lithography process. The device is provided on the temporary adhesive layer in an inverse manner such that a backside of the device is exposed. Additionally, the method includes attaching a flexible transfer substrate to the backside of the device, and removing the temporary adhesive layer by decomposing the temporary adhesive layer by employing a solvent and/or UV-light.

According to another aspect of the present disclosure, a flexible electronic device, particularly an optoelectronic device, is provided. The flexible electronic device is fabricated by a method for producing a flexible device according to any embodiments described herein.

According to a further aspect of the present disclosure, a method for producing a flexible arrangement of a plurality of flexible electronic devices is provided. The method includes providing a support substrate, coating the support substrate with an adhesive layer, depositing one or more layers of functional material on the adhesive layer, and patterning the one or more layers of functional materials to provide a plurality of electronic devices having a microstructure. The plurality of electronic devices are provided on the adhesive layer in an inverse manner such that a backside of the plurality of electronic devices is exposed. Additionally, the method includes attaching the flexible substrate to the backside of the plurality of electronic devices. Further, the method includes decomposing the adhesive layer for separating the plurality of electronic devices from the adhesive layer.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A to 1E show schematic illustrations of exemplary method stages of a method for producing a flexible device according to embodiments described herein;

FIG. 2 shows a flowchart for illustrating a method for producing a flexible device according to embodiments described herein;

FIG. 3 shows a flexible device produced by a method for producing a flexible device according to embodiments described herein;

FIGS. 4A to 4E show exemplary method stages of a method for producing an arrangement of a plurality of flexible electronic devices according to embodiments described herein;

FIG. 5A shows a schematic side view of an arrangement of a plurality of flexible electronic devices according to embodiments described herein;

FIG. 5B shows a schematic top view of the arrangement of a plurality of flexible electronic devices shown in FIG. 5A; and

FIG. 6 shows a flowchart for illustrating a method for producing a flexible arrangement of a plurality of flexible electronic devices according to embodiments described herein;

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

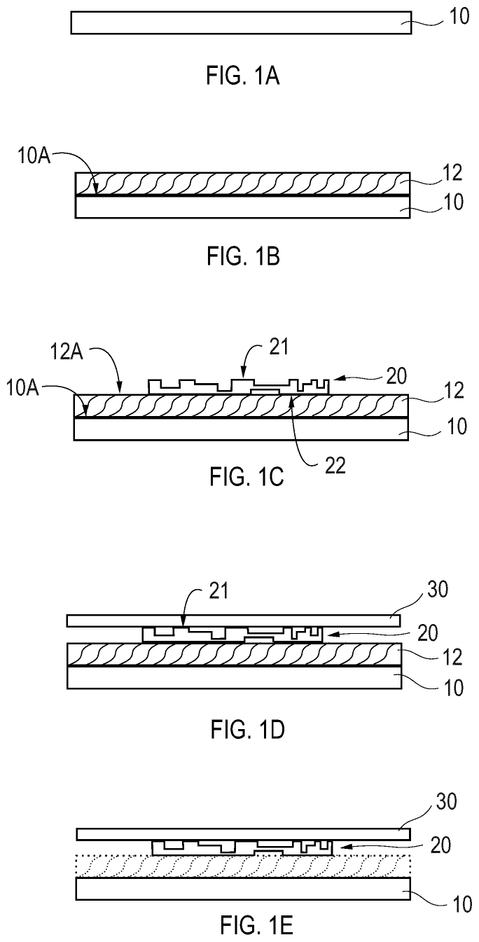

With exemplary reference to FIGS. 1A to 1E, embodiments of a method for producing a flexible device according to the present disclosure are described. According to embodiments which can be combined with any other embodiments described herein, the method includes providing a support substrate 10, as exemplarily shown in FIG. 1A. For example, the support substrate can be a rigid substrate, e.g. a rigid plate. Alternatively, the support substrate can be a flexible substrate, e.g. a web or a foil.

Additionally, the method includes coating the support substrate 10 with an adhesive layer 12, as exemplarily shown in FIG. 1B. In particular, coating the support substrate 10 with the adhesive layer 12 typically includes providing the adhesive layer 12 on a top surface 10A of the support substrate 10, particularly in direct contact with the top surface 10A of the support substrate 10. The adhesive layer can be a layer including an adhesive material or consisting of an adhesive material. An “adhesive material” can be understood as a material having adhesive properties. For instance, the adhesive material can be a polymeric adhesive material, e.g. a water-soluble synthetic polymer, particularly polyvinyl alcohol (PVA). Alternatively or additionally, the adhesive layer may include or consist of a light sensitive material, particularly a photoresist.

For instance, the photoresist can be a positive photoresist. A positive photoresist can be understood as a type of photoresist in which the portion of the photoresist that is exposed to light becomes soluble to a photoresist developer. The unexposed portion of the positive photoresist remains insoluble to the photoresist developer. Alternatively, the photoresist can be a negative photoresist. A negative can be understood as a type of photoresist in which the portion of the photoresist that is exposed to light becomes insoluble to a photoresist developer. The unexposed portion of the photoresist is dissolved by the photoresist developer.

With exemplary reference to FIG. 1C, the method further includes providing a device 20 having a microstructure on the adhesive layer 12. In particular, providing the device 20 on the adhesive layer 12 typically includes providing the device 20 on a top surface 12A of the adhesive layer 12, particularly in direct contact with the top surface 12A of the adhesive layer 12.

For example, the device can be an electronic device, particularly a micro-electronic device. For instance, providing the device 20 may include producing the device through one or more layer deposition processes and one or more layer structuring processes. Additionally, as exemplarily shown in FIG. 1D, the method further includes attaching a flexible substrate 30 to the device 20, particularly on an exposed surface of the device 20. Typically, the exposed surface of the device 20 is a backside 21 of the device. The flexible substrate which is attached to the device can be a web, a foil or a tape of flexible material.

Further, as exemplarily shown in FIG. 1E, the method includes removing the adhesive layer 12. In particular, removing the adhesive layer typically includes decomposing the adhesive layer, e.g. by employing a chemical or physico-chemical material decomposition process.

Accordingly, embodiments of the method for producing a flexible device as described herein are improved compared to conventional methods. In particular, embodiments of the present disclosure beneficially provide for an improved transfer of a flexible device from a support substrate to a flexible substrate. For instance, in the state of the art, a device is manufactured on a support substrate and subsequently mechanically separated from the support substrate which can cause damages to the device due to mechanical loads occurring during separation of the device from the support substrate. In contrast, embodiments of the present disclosure have the advantage, that the device can be transferred to a flexible substrate in a simple and device preserving way. Accordingly, embodiments of the method as described herein beneficially provide for reducing or even eliminating the risk of damaging the flexible device, particularly during separation of the device from a carrier employed during device fabrication. As a result, flexible devices produced by the method as described herein are of higher quality compared to conventionally produced flexible devices.

Before various further embodiments of the present disclosure are described in more detail, some aspects with respect to some terms used herein are explained.

In the present disclosure, a “flexible device” can be understood as a bendable device. In particular, a “flexible device” can be understood as a device including one or more layers of functional materials. The total number N of layers of functional materials of the flexible device can be 1≤N≤10, particularly 2≤N≤5. Further, the individual layer(s) of the one or more layers can have a layer thickness T of 50 nm≤T≤100 μm, particularly a layer thickness T of 100 nm≤T≤75 μm, more particularly a layer thickness T of 150 nm≤T≤50 μm or 150 nm≤T≤25 μm.

For example, the one or more layers can be provided by using a coating process, e.g. a spin coating process, and/or a layer deposition process, e.g. a physical vapor deposition (PVD) process and/or a chemical vapor deposition (CVD) process and/or a plasma-enhanced chemical vapor deposition (PECVD) process. Further, the one or more layers can include a microstructure, particularly a microstructured pattern. For instance, the microstructure can be produced by using an imprint process and/or a lithography process and/or an etching process, e.g. a wet or dry etching process. In the present disclosure, the term “device” may refer to a “flexible device” as described herein.

In the present disclosure, a “support substrate” can be understood as a substrate configured for providing support for a flexible device as described herein. In particular, a “support substrate” can be understood as a substrate suitable for providing a support during device fabrication. In other words, in the present disclosure a “support substrate” may be understood as a carrier substrate used during device fabrication. Accordingly, the support substrate can be a temporary carrier substrate which does not form part of the final product, i.e. the flexible device. For instance, the support substrate can be a rigid substrate, e.g. rigid carrier substrate, for example a plate of rigid material. For example, the rigid substrate may be a wafer or a glass plate, particularly a display glass plate. Alternatively, the support substrate can be a flexible substrate, e.g. a flexible carrier-web or a foil.

In the present disclosure, an “adhesive layer” can be understood as a layer having adhesive properties. For instance, the adhesive layer may include or consist of an adhesive material. In particular, an “adhesive layer” may be understood as a layer configured for providing adhesion between a support substrate as described herein and a device as described herein. In other words, the adhesive layer can be understood as a layer which is configured for providing an adhesive force for attaching a device as described herein to a support substrate as described herein. In particular, the adhesive layer can be provided on the support substrate such that a device to be produced on top of the adhesive layer can be held by the support substrate via the adhesive layer. Accordingly, typically the adhesive layer is an intermediate layer provided between the support substrate and the device. For example, the adhesive layer can include or consist of a polymeric adhesive material, e.g. a water-soluble synthetic polymer, particularly polyvinyl alcohol (PVA). Alternatively or additionally, the adhesive layer may include or consist of a light sensitive material, e.g. a positive photoresist or a negative photoresist.

In the present disclosure, a “flexible substrate” can be understood as a bendable substrate. For instance, the “flexible substrate” can be a “foil” or a “web”. For example, the flexible substrate as described herein may include materials like PET, HC-PET, PE, PI, PU, TaC, OPP, CPP, one or more metals, paper, combinations thereof, and already coated substrates like Hard Coated PET (e.g. HC-PET, HC-TaC) and the like. In some embodiments, the flexible substrate is a COP substrate provided with an index matched (IM) layer on both sides thereof. For example, the thickness of the flexible substrate can be 20 μm or more and 1 mm or less. In particular, the thickness of the flexible substrate can be from 50 μm to 200 μm.

According to some embodiments which can be combined with other embodiments described herein, the adhesive layer includes a decomposable material. In the present disclosure, a “decomposable material” can be understood as a material which is decomposable by exposing the material to a solvent, particularly an aqueous solvent. Additionally or alternatively, the decomposable material may be a material which is decomposable by the material to light, particularly UV-light. Accordingly, the decomposable material may include or consist of a light sensitive material, e.g. a positive photoresist or a negative photoresist.

As exemplarily indicated in FIG. 1E, removing the adhesive layer may include decomposing the adhesive layer, e.g. by using a solvent, particularly by using an aqueous solvent. Accordingly, decomposing the adhesive layer may include dissolving the adhesive layer

For instance, decomposing the adhesive layer by using a solvent may include spraying the solvent onto the adhesive layer. Alternatively, decomposing the adhesive layer by using a solvent may include dipping the adhesive layer into a solvent. In particular, the support substrate and the adhesive layer provided on top of the support substrate may be dipped into the solvent in order to decompose, particularly dissolve, the adhesive layer.

Accordingly, according to some embodiments which can be combined with other embodiments described herein, the decomposable material can be a dissolvable material, particularly a water-soluble material.

Additionally or alternatively, decomposing the adhesive layer may include exposing the adhesive layer, particularly the decomposable material of the adhesive layer, to light, particularly UV-light. In particular, in the case that the adhesive layer includes or consists of a positive photoresist, for removing the adhesive layer, the adhesive layer is exposed to light and subsequently exposed to a photoresist developer. In the case that the adhesive layer includes or consists of a negative photoresist, the adhesive layer is directly exposed to a photoresist developer, i.e. without exposing the adhesive layer to light.

Accordingly, according to some embodiments which can be combined with other embodiments described herein, the decomposable material can be a light-sensitive material. For example, the decomposable material can be a positive photo resist material. Alternatively, the decomposable material can be a negative photo resist material.

According to some embodiments which can be combined with other embodiments described herein, providing the device having the microstructure on the adhesive layer includes depositing one or more layers of functional materials. For example, typically depositing one or more layers of functional materials includes coating the adhesive layer with one or more layers of functional materials. Additionally or alternatively, depositing one or more layers of functional materials on the adhesive layer by using a vapor deposition process, e.g. a physical vapor deposition (PVD) process and/or a chemical vapor deposition (CVD) process and/or a plasma-enhanced chemical vapor deposition (PECVD) process.

In the present disclosure, a “functional material” can be understood as a material which possess particular native properties and functions, for example, ferroelectricity and/or piezoelectricity and/or magnetism and/or energy storage functions. For instance, a functional material can be a material selected from the group consisting of ceramic materials, metals, and organic materials such as polymers. In particular, functional materials can beneficially be used in electromagnetic applications from KHz to THz and at optical frequencies where the plasmonic properties of metals assume particular importance. Further, functional materials can beneficially be used in electronic devices, e.g. for conducting electricity, storing energy storage or for providing solar harvesting functions.

According to some embodiments which can be combined with other embodiments described herein, providing the device having the microstructure on the adhesive layer further includes patterning the one or more layers of functional materials. In particular, patterning the one or more layers of functional materials typically includes structuring the one or more layers of functional materials. For example, structuring the one or more layers of functional materials can include using an imprint process and/or a lithography process and/or an etching process, e.g. a wet or dry etching process. In FIG. 1C, a device 20 having a microstructure is schematically shown. As exemplarily shown in FIG. 1C, typically the device 20 is at least partially in contact with the adhesive layer 12. It is to be understood that typically the device is fabricated on the adhesive layer in an inverse manner, i.e. a top side 22 of the device is in contact with adhesive layer and a backside 21 of the device is exposed as exemplarily shown in FIG. 1C.

FIG. 1D shows a flexible substrate 30 attached to the device 20. According to some embodiments which can be combined with other embodiments described herein, attaching the flexible substrate to the device includes attaching the flexible substrate to the device via an adhesive provided on the flexible substrate. Typically, the adhesive provided on the flexible substrate is configured for providing adhesion, i.e. adhesive force, between the device 20 and the flexible substrate 30. It is to be understood that according to embodiments which can be combined with other embodiments described herein, that attaching the flexible substrate to the device typically includes attaching the flexible substrate to a backside 21 of the device 20, as exemplarily shown in FIG. 1D.

According to a further aspect of the present disclosure, a flexible arrangement of a plurality of electronic devices provided on a flexible substrate is provided. The plurality of flexible electronic devices are produced by providing a support substrate, coating the support substrate with an adhesive layer, depositing one or more layers of functional material on the adhesive layer, patterning the one or more layers of functional materials to provide the a plurality of electronic devices having a microstructure. The plurality of electronic devices are provided on the adhesive layer in an inverse manner, such that a backside of the plurality of electronic devices is exposed. Additionally, the method includes attaching the flexible substrate to the backside of the plurality of electronic devices. Further, the method includes decomposing the adhesive layer for separating the plurality of electronic devices from the adhesive layer.

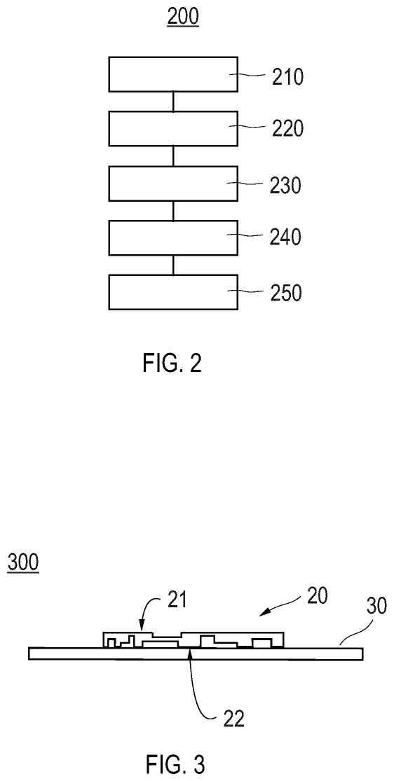

With exemplary reference to the flowchart shown in FIG. 2, a particular example of a method 200 for producing a flexible device is described, which can be combined with other embodiments described herein. The method 200 includes providing a support substrate (block 210) and coating the support substrate with a temporary adhesive layer (block 220). The temporary adhesive layer consists of a decomposable material. The decomposable material is decomposable by exposing the decomposable material to a solvent, particularly an aqueous solvent. Additionally or alternatively, the decomposable material is decomposable by exposing the decomposable material to light, particularly to UV-light. Additionally, the method includes providing a device (block 230) having a microstructure on the temporary adhesive layer by employing an imprint process and/or a lithography process. The device is provided on the temporary adhesive layer in an inverse manner, such that a backside of the device is exposed. Further, the method includes attaching a flexible transfer substrate to the backside of the device (block 240) and removing the temporary adhesive layer (block 250) by decomposing the temporary adhesive layer by employing a solvent and/or light.

Accordingly, the device is separated from the temporary adhesive layer and consequently from the support substrate such that the device can be transferred to the flexible substrate without inducing any mechanical load or stress during the separation process on the device. As a result, beneficially the risk of damaging the flexible device can be substantially reduced or even eliminated.

FIG. 3 shows a flexible device 300 produced by a method for producing a flexible device according to embodiments described herein. In particular, as exemplarily shown in FIG. 3, after separation of the device from the adhesive layer, i.e. after having conducted the method for producing a flexible device according to embodiments described herein, the backside 21 of the device is attached to the flexible substrate 30 and a top side 22 of the device 20 is exposed.

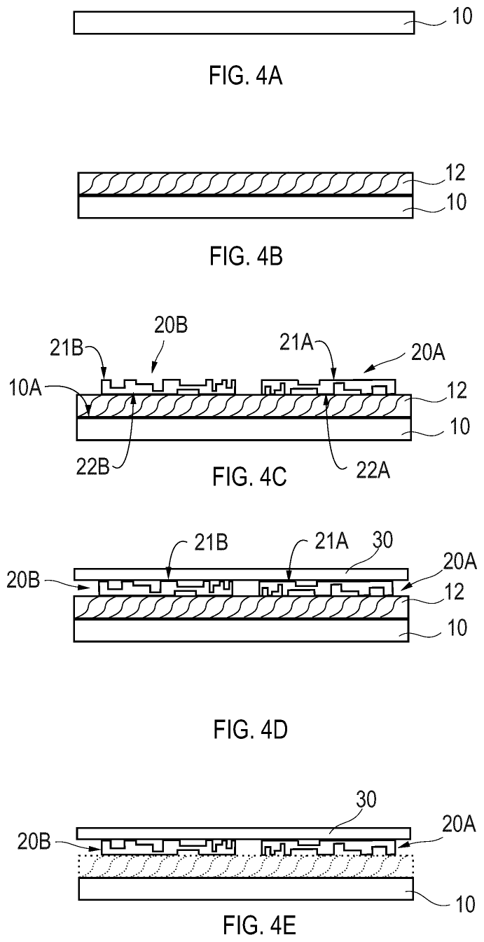

With exemplarily reference to FIGS. 4A to 4E and the flowchart shown in FIG. 6, a method 500 for producing an arrangement of a plurality of flexible electronic devices according to the present disclosure is described. The method includes providing a support substrate 10, as exemplarily shown in FIG. 4A and represented by block 510 in FIG. 6. Additionally, the method includes coating the support substrate 10 with an adhesive layer 12, as exemplarily shown in FIG. 4B and represented by block 520 in FIG. 6.

Further, the method includes depositing one or more layers of functional material on the adhesive layer, as exemplarily represented by block 530 in FIG. 6, and patterning the one or more layers of functional materials, as exemplarily represented by block 540 in FIG. 6, to provide a plurality of electronic devices having a microstructure.

As exemplarily shown in FIG. 4C, the plurality of electronic devices are provided on the adhesive layer 12 in an inverse manner, such that a backside of the plurality of electronic devices is exposed. In particular, for illustration purposes FIG. 4C shows a first flexible electronic device 20A and a second flexible electronic device 20B representing the plurality of electronic devices. The first electronic device 20A has a first backside 21A and a first top side 22A. The second electronic device 20B has a second backside 21B and a second top side 22B.

Further, the method includes attaching the flexible substrate 30 to the backside of the plurality of electronic devices, as exemplarily shown in FIG. 4D and represented by block 550 in FIG. 6. As exemplarily indicated in FIG. 4E, the method further includes decomposing the adhesive layer 12 for separating the plurality of electronic devices from the adhesive layer 12. Decomposing the adhesive layer is represented by block 560 in FIG. 6. Further, it is to be understood that the description with respect to the method for producing a flexible device as described herein, mutatis mutandis, may be applied to the method for producing a flexible arrangement of a plurality of flexible electronic devices.

Accordingly, beneficially a method for an arrangement of a plurality of flexible electronic devices is provided with which the risk of damaging the plurality of electronic devices, particularly during separation of the devices from a carrier employed during device fabrication, e.g. the support substrate as described herein, can be reduced or even eliminated.

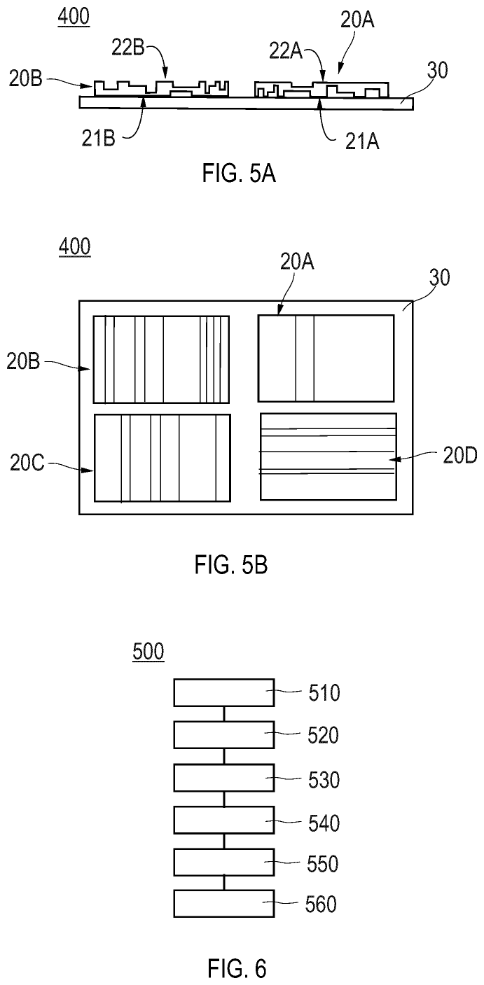

FIG. 5A shows a schematic side view of an arrangement 400 of a plurality of flexible electronic devices produced by a method for producing an arrangement of a plurality of flexible electronic devices according to embodiments described herein. In particular, as exemplarily shown in FIG. 5A, after separation of the device from the adhesive layer, i.e. after having conducted the method for producing an arrangement of a plurality of flexible electronic devices according to embodiments described herein, the backsides of the plurality of flexible electronic devices are attached to the flexible substrate 30 and the top sides of the plurality of flexible electronic devices are exposed.

FIG. 5B shows a schematic top view of FIG. 5A. In particular, as an example, FIG. 5B shows an arrangement 400 of a plurality flexible electronic devices provided on top of the flexible substrate, namely a first flexible electronic device 20A, a second flexible electronic device 20B, a third flexible electronic device 20C and a fourth flexible electronic device 20D. Further, as exemplarily shown in FIGS. 5A and 5B, the structure or pattern of the individual electronic devices may be different.

In view of the embodiments described herein, it is to be understood that compared to conventional production methods of flexible devices, embodiments so the present disclosure provide for improved methods with which the risk of damaging the flexible device, particularly during separation of the device from a carrier employed during device fabrication, can be reduced or even eliminated. Accordingly, embodiments as described herein also provide for flexible devices and arrangements with a plurality of flexible devices, particularly electronically flexible devices, of higher quality since possible damages during device fabrication are substantially reduced or avoided. Further, it is to be understood that embodiments as described herein are particularly well suited for roll-to-roll processes.

While the foregoing is directed to embodiments, other and further embodiments may be devised without departing from the basic scope, and the scope is determined by the claims that follow.

1. A method for producing a flexible device, the method comprising:
providing a support substrate,
coating the support substrate with an adhesive layer, the adhesive layer comprising a decomposable material, the decomposable material being a positive photo resist material or a negative photo resist material;
providing a device having a microstructure on the adhesive layer,
attaching a flexible substrate to the device, and
removing the adhesive layer.

2. (canceled)

3. The method of claim 1, wherein the decomposable material is a light-sensitive material.

4. The method of claim 1, wherein the decomposable material is a dissolvable material.

5. (canceled)

6. The method of claim 1, wherein providing the device having the microstructure on the adhesive layer comprises depositing one or more layers of functional materials.

7. The method of claim 6, wherein providing the device having the microstructure on the adhesive layer further comprises patterning the one or more layers of functional materials.

8. The method of claim 1, wherein attaching the flexible substrate to the device comprises attaching the flexible substrate to the device via an adhesive provided on the flexible substrate.

9. The method of claim 1, wherein removing the adhesive layer comprises decomposing the adhesive layer.

10. The method of claim 9, wherein decomposing the adhesive layer comprises dissolving the adhesive layer.

11. The method of claim 9, wherein decomposing the adhesive layer comprises exposing the adhesive layer to light.

12. The method of claim 1, wherein the support substrate is a flexible substrate.

13. A method for producing a flexible device, the method comprising:
providing a support substrate;
coating the support substrate with a temporary adhesive layer, the temporary adhesive layer consisting of a decomposable material, the decomposable material being decomposable by exposing the decomposable material to at least one of an aqueous solvent, and UV-light;
providing a device having a microstructure on the temporary adhesive layer by employing at least one of an imprint process and a lithography process, the device being provided on the temporary adhesive layer in an inverse manner such that a backside of the device is exposed;
attaching a flexible transfer substrate to the backside of the device; and
removing the temporary adhesive layer by decomposing the temporary adhesive layer by employing at least one of a solvent and light.

14. A flexible electronic device being fabricated by:
providing a support substrate,
coating the support substrate with an adhesive layer, the adhesive layer comprising a decomposable material, the decomposable material being a positive photo resist material or a negative photo resist material;
providing a device having a microstructure on the adhesive layer,
attaching a flexible substrate to the device, and
removing the adhesive layer.

15. A method for producing a flexible arrangement of a plurality of flexible electronic devices, the method comprising:
providing a support substrate,
coating the support substrate with an adhesive layer,
depositing one or more layers of functional material on the adhesive layer,
patterning the one or more layers of functional materials to provide the a plurality of electronic devices having a microstructure, the plurality of electronic devices being provided on the adhesive layer in an inverse manner, such that a backside of the plurality of electronic devices is exposed,
attaching a flexible substrate to the backside of the plurality of electronic devices,
decomposing the adhesive layer for separating the plurality of electronic devices from the adhesive layer.

16. The method of claim 10, wherein decomposing the adhesive layer comprises exposing the adhesive layer to light.

17. The method of claim 9, wherein decomposing the adhesive layer comprises exposing the adhesive layer to UV-light.

18. The method of claim 10, wherein decomposing the adhesive layer comprises exposing the adhesive layer to UV-light.

19. The method of claim 1, wherein the support substrate is a rigid carrier substrate.

20. The method of claim 9, wherein decomposing the adhesive layer comprises dissolving the adhesive layer by using an aqueous solvent.
